(19) United States
(12) Patent Application Publication
(10) Pub. No.: US 2015/0247250 A1
(43) Pub. Date: Sep. 3, 2015

(54) ABS PLASTIC SURFACE METAL LAYER AND METHOD OF MANUFACTURING THE SAME

(71) Applicant: Xiamen Runner Industrial Corporation, Xiamen (CN)

(72) Inventors: Shui Yu, Xiamen (CN); Yong-Liang Qiao, Xiamen (CN); Xian-Chao Zhang, Xiamen (CN); Min-Zen Lee, Xiamen (CN)

(21) Appl. No.: 14/624,985

(22) Filed: Feb. 18, 2015

(30) Foreign Application Priority Data
Feb. 28, 2014 (CN) 201410072507.8

(51) Int. Cl. C25D 3/12; C25D 5/50; C23C 28/02; C23C 14/34; C23C 14/16; C25D 5/40; C23C 14/02

(52) U.S. Cl. CPC C25D 3/12; C25D 5/40; C25D 5/50; C23C 14/022; C23C 14/3485; C23C 14/345; C23C 14/3464; C23C 14/165; C23C 28/021

(57) ABSTRACT

An ABS plastic surface metal layer and method of manufacturing the same, the structure of said ABS plastic surface metal layer includes: a chemical nickel layer 102 having thickness of 0.05˜0.5 μm, a watt nickel layer having thickness of 1˜3 μm, a semi-bright nickel layer having thickness of 3˜10μm, a PVD resistant alloy layer having thickness of 0.1˜2 μm, and a PVD color layer having thickness of 0.1˜0.3 μm. The manufacturing method includes: pre-processing the ABS plastic; electroplating the watt nickel layer and the semi-bright nickel layer in sequence; performing dragging process for the plated semi-bright nickel layer; performing hydrocarbon vacuum degreasing and baking processes for a dragged ABS plastic plated piece, then form the PVD resistant alloy layer and the PVD color layer, to complete the ABS plastic surface metal layer.

### BACKGROUND OF THE INVENTION

1. Field of the Invention

The present invention relates to a plastic surface processing technology, and in particular to an ABS plastic surface metal layer and method of manufacturing the same.

2. The Prior Arts

Presently, the plastics utilized extensively in automobile electroplating are ABS (Acrylonitrile Butadiene Styren), poly carbonate (PC)+ABS, and polyamide (PA); while the plastic utilized in the bathing and sanitary equipment is mainly ABS plastic. In general, plastic electroplating includes the following steps: firstly, a conductive film is produced on the plastic surface; and secondly, electroplating is used to make the conductive film thicker. As such, plastic electroplating can be divided mainly into two major processes. The first process is the preprocessing of plastic electroplating: degreasing→roughening→neutralizing→catalyzing→dispergating→chemical nickel. While the second process is plastic electroplating: nickel pre-plating→bright copper plating→semi-bright nickel plating→bright nickel plating→nickel sealing→bright chromium plating. In the processes mentioned above, large amount of waste water and heavy metal ions are produced, in which, the hexavalent chromium ions are detrimental to the environment and human body.

The danger of the electroplated chromium is that, it could cause harm to human skin, such that the skin is sensitive to the stimulation of hexavalent chromium. For the part of a body having contacted the chromate and chromic acid mist, such as hands, wrist, fore arm, and neck, dermatitis may appear. In case the hexavalent chromium enters the skin through cuts or bruises, it could cause chromium ulcer (also referred to as chromium sore). In addition, hexavalent chromium could cause harm to the respiration system, such as nasal septum perforation, pharyngitis, and pneumonia, to harm the internal organs. In case the hexavalent chromium intrudes through the digestive tract, it could cause degradation of smell and taste, or even the disappearance of smell and taste. High dosage of hexavalent chromium could corrode the internal organs. It could lead to degradation of stomach and intestine functions and stomach ache, or even ulcer of stomach and intestine, to cause harm to the liver. Trivalent chromium could harm the lung of human, experiment indicates that its toxicity is about 1% of that of the hexavalent chromium.

China Patent No. 201220188606 discloses an ABS plastic surface plated layer structure having dragging effect, the structure includes from inside to outside ABS plastic layer, chemical nickel layer, alkaline plated copper layer, dragged and plated nickel layer, and plated chromium layer.

The Environment Technology Periodical of Zhang Hua ( [symbol] ) published in April 2013 discloses an electroplating technology of automobile plastic decoration pieces and its functional test. In that periodical, function of copper electroplating is described in detail: copper has good extensibility and flexibility, and its thermal expansion coefficient is closer to that of plastic than other electroplated layers. The plating of about 15˜25 μm of smooth and flexible copper layer on the surface of the plastic accessory is favorable to increase the binding force between the accessory and the entire plated layer, heat resistance, and corrosion resistance, so that it may provide a buffer effect when the accessory is subject to outside temperature variations or impact of objects, to reduce the damage incurred. Therefore, copper electroplating is an indispensable part of plastic plating, its main function is to increase the binding force between plastic the subsequently electroplated layer, and to reduce the stress on the nickel layer.

Further, in Material Protection Periodical No. 44 of Ling Xi ( [symbol] ) published in November, 2011, is described the recent ion plating developments in China and other countries. According to that periodical, the ion film plating technology has replaced the chromium plating. In practice, due to various reasons, such as high production cost, and its function does not meet the requirement of actual application, the adoption of PVD film plating technology to replace the chromium electroplating technology is not successful, such that it can not be put into actual application. That periodical only describes an ideal state, it has not yet been put into actual production, thus it is not able to achieve a breakthrough, as shown in the detailed functional index.

Therefore, presently, the design and manufacturing of the ABS plastic surface metal layer is not quite satisfactory, and it has much room for improvement.

### SUMMARY OF THE INVENTION

In view of the problems and drawbacks of the prior art, the present invention provides an ABS plastic surface metal layer and method of manufacturing the same, that is simple in design and optimized in production, to overcome the shortcomings of the prior art.

An objective of the present invention is to provide an ABS plastic surface metal layer, to solve the problem of the existing ABS plastic plating, such as it requires to electroplate copper and chromium. With regard to copper plating, it could cause the deterioration of the corrosion resistance of the entire electroplated layer, thus it requires to plate a thick nickel layer to provide corrosion resistance protection. While the electroplating of hexavalent chromium is very harmful to its operator and environment.

Another objective of the present invention is to provide an ABS plastic surface metal layer manufacturing method, to produce such an ABS plastic surface metal layer.

The structure of ABS plastic surface metal layer, starting from the ABS plastic surface, is as follows: a chemical nickel layer, an watt nickel layer, a semi-bright nickel layer, a PVD resistant alloy layer, and a PVD color layer.

The thickness of the chemical nickel layer is 0.05 to 0.5 μm.

The thickness of the watt nickel layer is 1 to 3 μm.

The thickness of the semi-bright nickel layer is 3 to 10 μm.

The thickness of the PVD resistant alloy layer is 0.1 to 2 μm.

The PVD resistant alloy layer can be at least one of the following: ZrSi alloy (its atom number percentage is Zr 50-98, and Si 2-50), CrSi alloy (its atom number percentage is Cr 50-98, and Si 2-50), NiCr alloy (its atom number percentage is Ni 50-98, and Cr 5-50), TiSi alloy (its atom number percentage is Ti 50-98, and Si 2-50).

The thickness of the PVD color layer is 0.1 to 0.3; au.

The ABS plastic surface metal layer manufacturing method includes the follow steps:

(1) pre-processing ABS plastic, to process ABS plastic in the following sequence: chemical degreasing→roughening→neutralizing→catalyzing→dispergating→chemical nickel;

(2) electroplating the watt nickel layer and the semi-bright nickel layer in sequence for the pre-processed ABS plastic;

(3) performing drawing for the ABS plastic and semi-bright nickel layer;

(4) performing hydrocarbon vacuum degreasing and baking processes for the ABS plastic electroplated pieces after the drawing process; then form a PVD resistant alloy layer and a PVD color layer, to complete the ABS plastic surface metal layer.

In the step (1) above, the pre-processing can be performed according to the existing technology.

In the step (2) above, the electroplating of the watt nickel layer and the semi-bright nickel layer can be performed according to the well known nickel watt recipe, to electroplate the watt nickel layer first, then electroplate the semi-bright nickel layer. The thickness of the watt nickel layer is controlled at 1˜3 nm, while the thickness of the semi-bright nickel layer is controlled at 3˜10 nm.

In the step (3) above, the dragging process can be performed manually or automatically. The drawing machine rotation speed is 600˜1200 r/min. The dragging wheel can be nylon wheel, or flying wing wheel.

In the step (4) above, the product is hung onto the PVD film forming hanging tool to perform hydrocarbon vacuum degreasing and baking process. The degreasing duration is 3˜8 minutes (min), while the baking duration is 5˜10 min. In forming the PVD resistant alloy layer and the PVD color layer, said layers can be placed directly in a PVD oven to form the PVD resistant alloy layer and the PVD color layer according to the following steps:

(1) vacuuming: when vacuum reaches 2×10⁻² Pa, perform plasma glowing process, the ion current is 0.7˜1 A, bias is 150˜200V, duty ratio is 20%˜38%, Ar gas flowing speed is 100˜300 SCCM, duration is 5˜10 min, in achieving the purpose of enhanced cleaning;

(2) perform vacuuming: when vacuum reaches (3-9)×10⁻³ Pa, form a sputtered PVD resistant alloy layer. The parameters utilized are as follows: intermediate frequency impulse or DC power supply, power current 1˜20 A, deposition duration 5˜60 min, bias 80˜100V, duty ratio 20%˜38%, Ar gas flowing speed 60˜200 SCCM, N₂ gas flowing speed 0˜100 SCCM. The target for the PVD resistant alloy layer can be chosen from one of the following: ZrSi alloy target, CrSi alloy target, NiCr alloy target, TiSi alloy target, or simultaneous sputtering and deposition of Zr target and Si target, or simultaneous sputtering and deposition of Cr target and Si target, or simultaneous sputtering and deposition of Ni target and Cr target, or simultaneous sputtering and deposition of Ti target and Si target; and

(3) upon finishing forming the PVD resistant alloy layer, continue vacuuming for 3˜5 min, then form the PVD color layer, the parameters for this are as follows: multi-arc power current 70˜120 A, deposition duration 2˜5 min, bias is 80˜100V, duty ratio is 40%′ 80%, Ar gas flowing speed is 20˜200 SCCM, N₂ gas flowing speed 0˜200 SCCM, acetylene gas flowing speed 0˜150 SCCM, O₂ gas flowing speed 0˜150 SCCM. The metal target for PVD color layer can be selected from one of the following: pure Zr 99.99%, pure Ti 99.99%, and pure Cr 99.99%.

Between forming the PVD resistant alloy layer and the PVD color layer, a PVD transition layer has to be formed, the duration is 1˜5 min. Similarly, depending on the material of the PVD resistant alloy layer utilized, a PVD transition layer can be formed between the PVD plasma glowing and the PVD resistant alloy layer, the duration is 1˜5 min, with its purpose of increasing the binding force between the respective layers and reducing the stress between the respective layers

In the present invention, the manufacturing process for the ABS plastic plated piece can be shortened, to eliminate the hazard of chromium plating to the environment, and to solve the problem of product being burned out during chromium plating, thus raising the production yield and reducing the production cost significantly, while achieving material saving.

The advantages of the present invention can be summarized as follows:

1. Simplify the production process for the existing plated nickel drawing type product, to remove the restriction that in electroplating the ABS plastic, copper plating must be performed, thus shortening production process.

2. Adopt the PVD film plating technology to replace the existing chromium plating, to meet the function requirement of high end product for the bathing and sanitary equipment, as based on the following standards:
A. CASS=Copper-Accelerated Acetic Acid-Salt Spray (Fog) Testing (corrosion resistance test ASTM B368-09) . . . 0.8 h;
B. AASS=Acetic Acid-Salt Spray (Fog) Testing (salt mist test ASTM G85-9) . . . 0.48 h;
C. thermal cycling test −40° C. to 75° C. (ASME A112.18.1-2005/CSA B125.1-05) . . . 8 cycles.

3. Under the conditions of fulfilling the functional requirement, the thickness of nickel layer can be reduced, from the ordinary at 10˜20 μm to 3˜5 μm, hereby saving metal resources.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from this detailed descriptions.

### BRIEF DESCRIPTION OF THE DRAWINGS

FIG. 1 is a schematic diagram of a structure of an ABS plastic surface metal layer according to the present invention; and

FIG. 2 is a flowchart of the steps of an ABS plastic surface metal layer manufacturing method according to the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

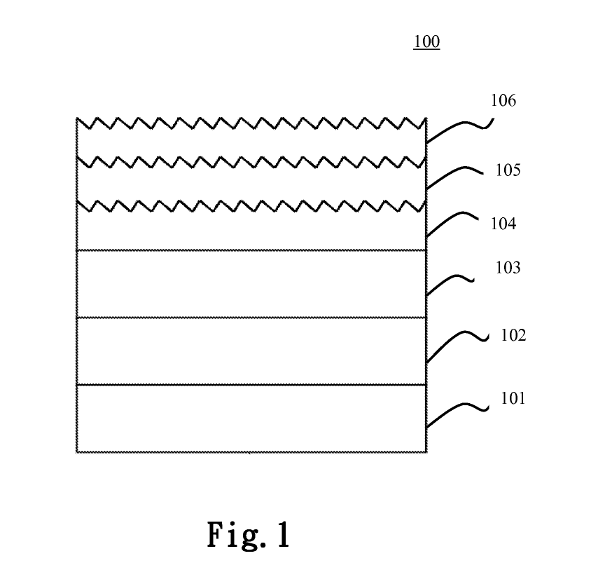

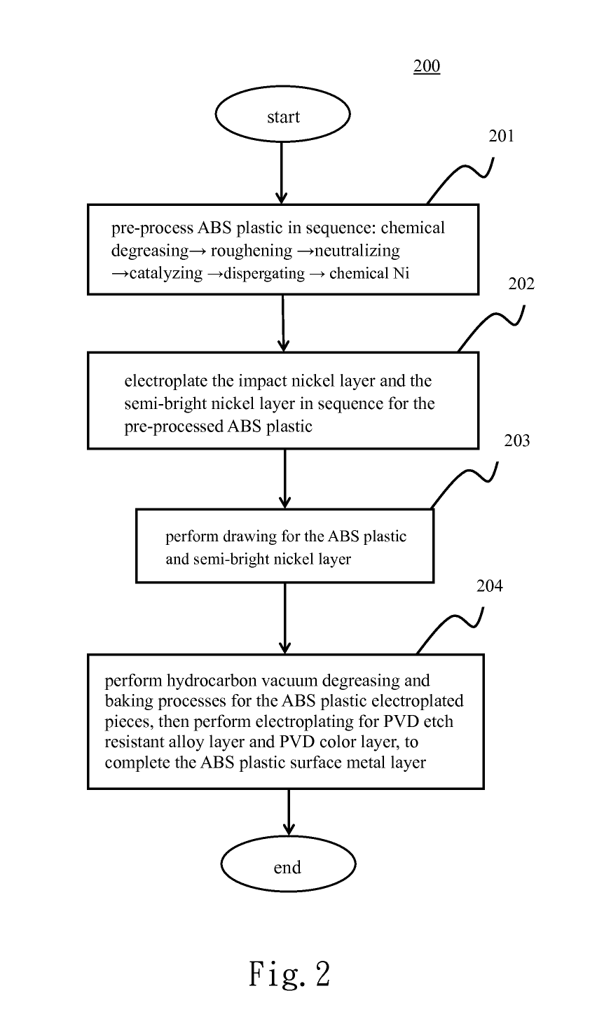

In the following Embodiments 1 to 7, refer to FIGS. 1 and 2 respectively for a schematic diagram of a structure of an ABS plastic surface metal layer according to the present invention; and a flowchart of the steps of an ABS plastic surface metal layer manufacturing method according to the present invention.

### Embodiment 1

As shown in FIG. 1, the structure of ABS plastic surface metal layer 100, starting from the ABS plastic 101 in sequence, is as follows: a chemical nickel layer 102 having a thickness of 0.05 μm, a watt nickel layer 103 having a thickness of 1 μm, a semi-bright nickel layer 104 having a thickness of 10 μm, a PVD resistant alloy layer 105 having a thickness of 0.1 μm, the resistant alloy can be a ZrSi alloy (the ZrSi atom number percentage is Zr 50 and Si 50) and a PVD color layer 106 having a thickness of 0.3 μm, that is made of ZrN.

As shown in FIG. 2, the ABS plastic surface metal layer manufacturing method 200 includes the following steps:

(1) pre-processing the ABS plastic, to process ABS plastic in the following sequence: chemical degreasing→roughening→neutralizing→catalyzing→dispergating→chemical nickel; the process flow proceed according to the existing technology, while the thickness of the plated chemical nickel layer 102 is 0.05 μm (step 201);

(2) electroplating the ABS plastic: after the first step of pre-processing ABS plastic, perform electroplating the watt nickel layer 103 and the semi-bright nickel layer 104. The electroplating of the watt nickel layer 103 utilizes the well known watt nickel recipe, the thickness of the watt nickel layer 103 is controlled at 1 μm; then perform electroplating the semi-bright nickel layer 104 utilizing the well known semi-bright nickel recipe, the thickness of the semi-bright nickel layer 104 is controlled at 10 μm, to meet the requirement of thickness for the dragging process (step 202);

(3) perform dragging process for ABS plastic plated nickel layer: perform dragging process after the second step of electroplating ABS plastic. The dragging can be performed manually or automatically. The rotation speed of the dragging machine is 1200 r/min, while the dragging wheel can be a nylon wheel (step 203); and

(4) after the dragging process, the ABS plastic plated piece is performed hydrocarbon vacuum degreasing and baking processes; to hang the product onto the PVD film forming hanging tool, to perform hydrocarbon vacuum degreasing and baking processes; the degreasing duration is 3 min, while the baking duration is 5 minutes (min). Afterwards, the ABS plastic plated piece is formed a PVD resistant alloy layer 105 and a PVD color layer 106. To hang the ABS plastic plated piece directly into the PVD oven, to form the PVD resistant alloy layer 105 and the PVD color layer 106 according to the following steps (step 204):

(1) vacuuming: when vacuum reaches 2×10⁻² Pa, perform plasma glowing process, the ion current is 0.7 A, bias is 200V, duty ratio is 38%, Ar gas flowing speed is 300 SCCM, duration is 10 min, in achieving the purpose of further cleaning;

(2) perform vacuuming: when vacuum reaches 9×10⁻³ Pa, form a sputtered PVD resistant alloy layer 105. The parameters utilized are as follows: DC power supply, power current 20 A, deposition duration 5 min, bias is 80V, duty ratio is 38%, Ar gas flowing speed is 200 SCCM, The target for the PVD resistant alloy layer 105 can be a ZrSi alloy target; and

(3) upon finished forming the PVD resistant alloy layer 105, continue vacuuming for 3 min, then form the PVD color layer 106, the parameters for this are as follows: multi-arc power current 120 A, deposition duration 5 min, bias 80V, duty ratio 80%, Ar gas flowing speed 20 SCCM, N₂ gas flowing speed 200 SCCM. The metal target for PVD color layer 106 can be pure Zr 99.99%.

Then, perform bathing and sanitary equipment tests based on the following standards:
A. CASS=Copper-Accelerated Acetic Acid-Salt Spray (Fog) Testing (corrosion resistance test ASTM B368-09) . . . 0.8 h;
B. AASS=Acetic Acid-Salt Spray (Fog) Testing (salt mist test ASTM G85-9) . . . 48 h;
C. thermal cycling test −40° C. to 75° C. (ASME A112.18.1-2005/CSA B125.1-05) . . . 8 cycles.
   The tests are conducted and passed for all the items mentioned above.

### Embodiment 2

As shown in FIG. 1, the structure of ABS plastic surface metal layer 100, starting from the ABS plastic 101 in sequence, is as follows: a chemical nickel layer 102 having a thickness of 0.5 μm, a watt nickel layer 103 having a thickness of 3 μm, a semi-bright nickel layer 104 having a thickness of 3 μm, a PVD resistant alloy layer 105 having a thickness of 0.3 μm, the resistant alloy can be a CrSi alloy (the CrSi atom number percentage is Cr 98 and Si 2), and a PVD color layer 106 having a thickness of 0.1 μm, that is made of ZrCN.

As shown in FIG. 2, the ABS plastic surface metal layer manufacturing method 200 includes the following steps:

(1) pre-processing the ABS plastic, to process ABS plastic in the following sequence: chemical degreasing→roughening→neutralizing→catalyzing→dispergating→chemical nickel; the process flow proceeds according to the existing technology, while the thickness of the plated chemical nickel layer 102 is 0.5 μm (step 201);

(2) electroplating the ABS plastic: after the first step of pre-processing ABS plastic, perform electroplating the watt nickel layer 103 and the semi-bright nickel layer 104. The electroplating of the watt nickel layer 103 utilizes the well known watt nickel recipe, the thickness of the watt nickel layer 103 is controlled at 3 μm; then perform electroplating the semi-bright nickel layer 104 utilizing the well known semi-bright nickel recipe, the thickness of the semi-bright nickel layer 104 is controlled at 3 μm, to meet the requirement of thickness for the dragging process (step 202);

(3) performing dragging process for ABS plastic plated nickel layer: perform dragging process after the second step of electroplating ABS plastic. The dragging can be performed manually or automatically. The rotation speed of the dragging machine is 600 r/min, while the dragging wheel can be a flying wing wheel (step 203); and

(4) after the dragging process, the ABS plastic plated piece is performed hydrocarbon vacuum degreasing and baking processes; to hang the product onto the PVD film forming hanging tool, to perform hydrocarbon vacuum degreasing and baking processes; the degreasing duration is 8 min, while the baking duration is 10 min. Afterwards, the ABS plastic plated piece is formed a PVD resistant alloy layer 105 and a PVD color layer 106. To hang the ABS plastic plated piece directly into the PVD oven, to form the PVD resistant alloy layer 105 and the PVD color layer 106 according to the following steps (step 204):

(1) vacuuming: when vacuum reaches 2×10⁻² Pa, perform plasma glowing process, the ion current is 1 A, bias is 200V, duty ratio is 20%, Ar gas flowing speed is 100 SCCM, duration is 5 min, in achieving the purpose of further cleaning;

(2) perform vacuuming: when vacuum reaches 3×10⁻³ Pa, form a sputtered PVD resistant alloy layer 105. The parameters utilized are as follows: DC power supply, power current 1 A, deposition duration 60 min, bias is 100V, duty ratio is 38%, Ar gas flowing speed is 60 SCCM, N₂ gas flowing speed is 50 SCCM, The target for the PVD resistant alloy layer 105 can be a CrSi alloy target; and

(3) upon finished forming the PVD resistant alloy layer 105, continue vacuuming for 3 min, then form the PVD color layer 106, the parameters for this are as follows: multi-arc power current 100 A, deposition duration 5 min, bias is 100V, duty ratio is 80%, Ar gas flowing speed is 20 SCCM, N₂ gas flowing speed 100 SCCM, acetylene gas flowing speed 50 SCCM. The metal target for PVD color layer 106 can be pure Zr 99.99%.

Between the PVD resistant alloy layer 105 and the PVD color layer 106, a PVD transition layer has to be formed by sputtering a CrSi alloy using DC current, the power current is 1 A. For multi-arc Zr sputtering, the current is 100 A, deposition duration is 5 min, bias is 100V, duty cycle is 38%, Ar gas flowing speed is 100 SCCM. Similarly, depending on the material of the PVD resistant alloy layer 105 utilized, a PVD transition layer can be formed between the PVD plasma glowing and the PVD resistant alloy layer 105. The technology involved is sputtering the Cr using DC, the current is 2 A, bias is 100V, duty cycle is 38%, Ar gas flowing speed is 100 SCCM, with its duration of 5 minutes. Its purpose is to increase the binding force between the respective layers and reduce the stress between the respective layers

Then, perform bathing and sanitary equipment tests based on the following standards:
A. CASS=Copper-Accelerated Acetic Acid-Salt Spray (Fog) Testing (corrosion resistance test ASTM B368-09) . . . 0.8 h;
B. AASS=Acetic Acid-Salt Spray (Fog) Testing (salt mist test ASTM G85-9) . . . 0.48 h;
C. thermal cycling test −40° C. to 75° C. (ASME A112.18.1-2005/CSA B125.1-05) . . . 8 cycles.
   The tests are conducted and passed for all the items mentioned above.

### Embodiment 3

As shown in FIG. 1, the structure of ABS plastic surface metal layer 100, starting from the ABS plastic 101 in sequence, is as follows: a chemical nickel layer 102 having a thickness of 0.2 μm, a watt nickel layer 103 having a thickness of 2 an, a semi-bright nickel layer 104 having a thickness of 3 μm, a PVD resistant alloy layer 105 having a thickness of 2 μm, the resistant alloy can be an NiCr alloy (the NiCr atom number percentage is Ni 50 and Cr 50), and a PVD color layer 106 having a thickness of 0.2 μm, such that its color is of Cr color.

As shown in FIG. 2, the ABS plastic surface metal layer manufacturing method 200 includes the following steps:

(1) pre-processing the ABS plastic, to process ABS plastic in the following sequence: chemical degreasing→roughening→neutralizing→catalyzing→dispergating→chemical nickel; the process flow proceeds according to the existing technology, while the thickness of the plated chemical nickel layer 102 is 0.2 μm (step 201);

(2) electroplating the ABS plastic: after the first step of pre-processing ABS plastic, perform electroplating the watt nickel layer 103 and the semi-bright nickel layer 104. The electroplating of the watt nickel layer 103 utilizes the well known watt nickel recipe, the thickness of the watt nickel layer 103 is controlled at 2 μm; then perform electroplating the semi-bright nickel layer 104 utilizing the well known semi-bright nickel recipe, the thickness of the semi-bright nickel layer 104 is controlled at 3 μm, to meet the requirement of thickness for the dragging process (step 202);

(3) perform dragging process for ABS plastic plated nickel layer: perform dragging process after the second step of electroplating ABS plastic. The dragging can be performed manually or automatically. The rotation speed of the dragging machine is 1000 r/min, while the dragging wheel can be a nylon wheel (step 203); and

(4) after the dragging process, the ABS plastic plated piece is performed hydrocarbon vacuum degreasing and baking processes; to hang the product onto the PVD film forming hanging tool, to perform hydrocarbon vacuum degreasing and baking processes; the degreasing duration is 5 min, while the baking duration is 8 min. Afterwards, the ABS plastic plated piece is formed a PVD resistant alloy layer 105 and a PVD color layer 106. To hang the ABS plastic plated piece directly into the PVD oven, to form the PVD resistant alloy layer 105 and the PVD color layer 106 according to the following steps (step 204):

(1) vacuuming: when vacuum reaches 2×10⁻² Pa, perform plasma glowing process, the ion current is 0.8 A, bias is 170V, duty ratio is 35%, Ar gas flowing speed is 300 SCCM, duration is 5 min, in achieving the purpose of further cleaning;

(2) perform vacuuming: when vacuum reaches 7×10⁻³ Pa, form a sputtered PVD resistant alloy layer 105. The parameters utilized are as follows: immediate frequency impulse power supply, power current 10 A, deposition duration 60 min, bias is 80V, duty ratio is 20%, Ar gas flowing speed is 200 SCCM, N₂ gas flowing speed is 50 SCCM, The target for the PVD resistant alloy layer 105 can be a NiCr alloy target; and

(3) upon finishing forming the PVD resistant alloy layer 105, continue vacuuming for 3 min, then form the PVD color layer 106, the parameters for this are as follows: multi-arc power current 70 A, deposition duration 5 min, bias is 100V, duty ratio is 80%, Ar gas flowing speed is 120 SCCM. The metal target for PVD color layer 106 can be pure Cr 99.99%.

Then, perform bathing and sanitary equipment tests based on the following standards:
A. CASS=Copper-Accelerated Acetic Acid-Salt Spray (Fog) Testing (corrosion resistance test ASTM B368-09) . . . 0.8 h;
B. AASS=Acetic Acid-Salt Spray (Fog) Testing (salt mist test ASTM G85-9) . . . 0.48 h;
C. thermal cycling test −40° C. to 75° C. (ASME A112.18.1-2005/CSA B125.1-05) . . . 8 cycles.
   The tests are conducted and passed for all the items mentioned above.

### Embodiment 4

As shown in FIG. 1, the structure of ABS plastic surface metal layer 100, starting from the ABS plastic 101 in sequence, is as follows: a chemical nickel layer 102 having a thickness of 0.2 μm, a watt nickel layer 103 having a thickness of 2 μm, a semi-bright nickel layer 104 having a thickness of 5 μm, a PVD resistant alloy layer 105 having a thickness of 0.5 μm, the resistant alloy can be a TiSi alloy (the TiSi atom number percentage is Ti 90 and Si 10), and a PVD color layer 106 having a thickness of 0.2 μm, that is made of ZrN.

As shown in FIG. 2, the ABS plastic surface metal layer manufacturing method 200 includes the following steps:

(1) pre-processing the ABS plastic, to process ABS plastic in the following sequence: chemical degreasing→roughening→neutralizing→catalyzing→dispergating→chemical nickel; the process flow proceeds according to the existing technology, while the thickness of the plated chemical nickel layer 102 is 0.2 μm (step 201);

(2) electroplating the ABS plastic: after the first step of pre-processing ABS plastic, perform electroplating the watt nickel layer 103 and the semi-bright nickel layer 104. The electroplating of the watt nickel layer 103 utilizes the well known watt nickel recipe, the thickness of the watt nickel layer 103 is controlled at 2 μm; then perform electroplating the semi-bright nickel layer 104 utilizing the well known semi-bright nickel recipe, the thickness of the semi-bright nickel layer 104 is controlled at 5 μm, to meet the requirement of thickness for the dragging process (step 202);

(3) perform dragging process for ABS plastic plated nickel layer: perform dragging process after the second step of electroplating ABS plastic. The dragging can be performed manually or automatically. The rotation speed of the dragging machine is 600 r/min, while the dragging wheel can be a flying wing wheel (step 203); and

(4) after the dragging process, the ABS plastic plated piece is performed hydrocarbon vacuum degreasing and baking processes; to hang the product onto the PVD film forming hanging tool, to perform hydrocarbon vacuum degreasing and baking processes; the degreasing duration is 6 min, while the baking duration is 6 min. Afterwards, the ABS plastic plated piece is formed a PVD resistant alloy layer 105 and a PVD color layer 106. To hang the ABS plastic plated piece directly into the PVD oven, to form the PVD resistant alloy layer 105 and the PVD color layer 106 according to the following steps (step 204):

(1) vacuuming: when vacuum reaches 2×10⁻² Pa, perform plasma glowing process, the ion current is 0.7 A, bias is 150V, duty ratio is 20%, Ar gas flowing speed is 150 SCCM, duration is 8 min, in achieving the purpose of further cleaning;

(2) perform vacuuming: when vacuum reaches 9×10⁻³ Pa, form a sputtered PVD resistant alloy layer 105. The parameters utilized are as follows: intermediate frequency impulse and DC power supply, intermediate frequency impulse power current 2 A, the sputtered target is pure silicon target, DC power current 10 A; the sputtered target is Ti target, deposition duration 25 min, bias is 80V, duty ratio is 25%, The target for the PVD resistant alloy layer 105 can be a Ti target, sputtered and deposited with a Si target at the same time; and

(3) upon finishing forming the PVD resistant alloy layer 105, continue vacuuming for 5 min, then form the PVD color layer 106, the parameters for this are as follows: multi-arc power current 70 A, deposition duration 5 min, bias is 100V, duty ratio is 80%, Ar gas flowing speed is 150 SCCM. The metal target for PVD color layer 106 can be pure Ti 99.99%.

Between the PVD resistant alloy layer 105 and the PVD color layer 106, a PVD transition layer has to be formed. The technology utilized is to sputter Ti using a DC current, the power current is 5 A. For multi-arc Cr sputtering, the current is 70 A, deposition duration is 1 min, bias is 100V, duty cycle is 80%, Ar gas flowing speed is 100 SCCM. Similarly, depending on the material of the PVD resistant alloy layer 105 utilized, a PVD transition layer can be formed between the PVD plasma glowing and the PVD resistant alloy layer 105. The technology involved is to sputter Ti using DC current, the DC current is 5 A, bias is 100V, duty cycle is 38%, Ar gas flowing speed is 200 SCCM, with its duration of 5 minutes. Its purpose is to increase the binding force between the respective layers and reduce the stress between the respective layers

Then, perform bathing and sanitary equipment tests based on the following standards:
A. CASS=Copper-Accelerated Acetic Acid-Salt Spray (Fog) Testing (corrosion resistance test ASTM B368-09) . . . 0.8 h;
B. AASS=Acetic Acid-Salt Spray (Fog) Testing (salt mist test ASTM G85-9) . . . 0.48 h;
C. thermal cycling test −40° C. to 75° C. (ASME A112.18.1-2005/CSA B125.1-05) . . . 8 cycles.
   The tests are conducted and passed for all the items mentioned above.

### Embodiment 5

As shown in FIG. 1, the structure of ABS plastic surface metal layer 100, starting from the ABS plastic 101 in sequence, is as follows: a chemical nickel layer 102 having a thickness of 0.2 μm, a watt nickel layer 103 having a thickness of 2 μm, a semi-bright nickel layer having a thickness of 4 μm, a PVD resistant alloy layer 105 having a thickness of 0.5 μm, the resistant alloy can be a CrSi alloy (the CrSi atom number percentage is Cr 90 and Si 10), and a PVD color layer 106 having a thickness of 0.3 μm, that is made of ZrO.

As shown in FIG. 2, the ABS plastic surface metal layer manufacturing method 200 includes the following steps:

(1) pre-processing the ABS plastic, to process ABS plastic in the following sequence: chemical degreasing→roughening→neutralizing→catalyzing→dispergating→chemical nickel; the process flow proceeds according to the existing technology, while the thickness of the plated chemical nickel layer 102 is 0.2 μm (step 201);

(2) electroplating the ABS plastic: after the first step of pre-processing ABS plastic, perform electroplating the watt nickel layer 103 and the semi-bright nickel layer 104. The electroplating of the watt nickel layer 103 utilizes the well known watt nickel recipe, the thickness of the watt nickel layer 103 is controlled at 2 μm; then perform electroplating the semi-bright nickel layer 104 utilizing the well known semi-bright nickel recipe, the thickness of the semi-bright nickel layer 104 is controlled at 4 μm, to meet the requirement of thickness for the dragging process (step 202);

(3) perform dragging process for ABS plastic plated nickel layer: perform dragging process after the second step of electroplating ABS plastic. The dragging can be performed manually or automatically. The rotation speed of the dragging machine is 600 r/min, while the dragging wheel can be a flying wing wheel (step 203); and

(4) after the dragging process, the ABS plastic plated piece is performed hydrocarbon vacuum degreasing and baking processes; to hang the product onto the PVD film forming hanging tool, to perform hydrocarbon vacuum degreasing and baking processes; the degreasing duration is 3 min, while the baking duration is 10 min. Afterwards, the ABS plastic plated piece is formed a PVD resistant alloy layer 105 and a PVD color layer 106. To hang the ABS plastic plated piece directly into a PVD oven, to form the PVD resistant alloy layer 105 and the PVD color layer 106 according to the following steps (step 204):

(1) vacuuming: when vacuum reaches 2×10⁻² Pa, perform plasma glowing process, the ion current is 1 A, bias is 150V, duty ratio is 25%, Ar gas flowing speed is 200 SCCM, duration is 6 min, in achieving the purpose of further cleaning;

(2) perform vacuuming: when vacuum reaches 7×10⁻³ Pa, form a sputtered PVD resistant alloy layer 105. The parameters utilized are as follows: intermediate frequency impulse and DC power supply, intermediate frequency impulse power current 3 A, the sputtered target is pure silicon target, DC power current 12 A; the sputtered target is Cr target, deposition duration 25 min, bias is 80V, duty ratio is 25%, Ar gas flowing speed is 100 SCCM. The target for the PVD resistant alloy layer 105 can be a CrSi alloy target; and

(3) upon finishing forming the PVD resistant alloy layer 105, continue vacuuming for 5 min, then form the PVD color layer 106, the parameters for this are as follows: multi-arc power current 120 A, deposition duration 2 min, bias is 100V, duty ratio is 80%, Ar gas flowing speed is 20 SCCM, O₂ gas flowing speed is 150 SCCM. The metal target for PVD color layer 106 can be pure Zr 99.99%.

Between the PVD resistant alloy layer 105 and the PVD color layer 106, a PVD transition layer has to be formed. The technology utilized is to sputter Cr using a DC current, The parameters for this are as follows: power current 5 A, current 120 A for multi-arc Zr sputtering, deposition duration is 2 min, bias is 100V, duty cycle is 80%, Ar gas flowing speed is 100 SCCM. Similarly, depending on the material of the PVD resistant alloy layer 105 utilized, a PVD transition layer can be formed between the PVD plasma glowing and the PVD resistant alloy layer 105. The technology involved is to sputter Cr using DC, the current is 5 A, bias is 100V, duty cycle is 38%, Ar gas flowing speed is 100 SCCM, with its duration of 3 minutes. Its purpose is to increase the binding force between the respective layers and reduce the stress between the respective layers

Then, perform bathing and sanitary equipment tests based on the following standards:
A. CASS=Copper-Accelerated Acetic Acid-Salt Spray (Fog) Testing (corrosion resistance test ASTM B368-09) . . . 0.8 h;
B. AASS=Acetic Acid-Salt Spray (Fog) Testing (salt mist test ASTM G85-9) . . . 0.48 h;
C. thermal cycling test −40° C. to 75° C. (ASME A112.18.1-2005/CSA B125.1-05) . . . 8 cycles.
   The tests are conducted and passed for all the items mentioned above.

### Embodiment 6

As shown in FIG. 1, the structure of ABS plastic surface metal layer 100, starting from the ABS plastic 101 in sequence, is as follows: a chemical nickel layer 102 having a thickness of 0.2 μm, a watt nickel layer 103 having a thickness of 2 μm, a semi-bright nickel layer 104 having a thickness of 4 μm, a PVD resistant alloy layer 105 having a thickness of 0.5 μm, the resistant alloy can be a CrSi alloy (the CrSi atom number percentage is Cr 90 and Si 10), and a PVD color layer 106 having a thickness of 0.3 and that is made of ZrO.

As shown in FIG. 2, the ABS plastic surface metal layer manufacturing method 200 includes the following steps:

(1) pre-processing the ABS plastic, to process ABS plastic in the following sequence: chemical degreasing→roughening→neutralizing→catalyzing→dispergating→chemical nickel; the process flow proceeds according to the existing technology, while the thickness of the plated chemical nickel layer 102 is 0.2 μm (step 201);

(2) electroplating the ABS plastic: after the first step of pre-processing ABS plastic, perform electroplating the watt nickel layer 103 and the semi-bright nickel layer 104. The electroplating of the watt nickel layer 103 utilizes the well known watt nickel recipe, the thickness of the watt nickel layer 103 is controlled at 2 μm; then perform electroplating the semi-bright nickel layer 104 utilizing the well known semi-bright nickel recipe, the thickness of the semi-bright nickel layer 104 is controlled at 4 μm, to meet the requirement of thickness for the dragging process (step 202);

(3) perform dragging process for ABS plastic plated nickel layer: perform dragging process after the second step of electroplating ABS plastic. The dragging can be performed manually or automatically. The rotation speed of the dragging machine is 600 r/min, while the dragging wheel can be a flying wing wheel (step 203); and

(4) after the dragging process, the ABS plastic plated piece is performed hydrocarbon vacuum degreasing and baking processes; to hang the product onto the PVD film forming hanging tool, to perform hydrocarbon vacuum degreasing and baking processes; the degreasing duration is 3 min, while the baking duration is 10 min. Afterwards the ABS plastic plated piece is formed a PVD resistant alloy layer 105 and a PVD color layer 106. To hang the ABS plastic plated piece directly into the PVD oven, to form the PVD resistant alloy layer 105 and the PVD color layer 106 according to the following steps (step 204):

(1) vacuuming: when vacuum reaches 2×10⁻² Pa, perform plasma glowing process, the ion current is 1 A, bias is 150V, duty ratio is 25%, Ar gas flowing speed is 200 SCCM, duration is 6 min, in achieving the purpose of further cleaning

(2) perform vacuuming: when vacuum reaches 7×10⁻³ Pa, form a sputtered PVD resistant alloy layer 105. The parameters utilized are as follows: intermediate frequency impulse DC power supply, intermediate frequency impulse power current 3 A, for the sputtered target of pure silicon target, DC power current 12 A, for the sputtered target of Cr target, deposition duration 25 min, bias is 80V, duty ratio is 25%, Ar gas flowing speed is 100 SCCM. The target for the PVD resistant alloy layer 105 can be a CrSi alloy target; and

(3) upon finishing forming the PVD resistant alloy layer 105, continue vacuuming for 5 min, then form the PVD color layer 106, the parameters for this are as follows: multi-arc power current 120 A, deposition duration 2 min, bias is 100V, duty ratio is 80%, Ar gas flowing speed is 20 SCCM, O₂ gas flowing speed is 150 SCCM. The metal target for PVD color layer 106 can be pure Zr 99.99%.

Between the PVD resistant alloy layer 105 and the PVD color layer 106, a PVD transition layer has to be formed by sputtering Cr using a DC current. The parameters for this are as follows: power current 5 A, multi-arc Zr sputtering with current 120 A, deposition duration is 2 min, bias is 100V, duty cycle is 80%, Ar gas flowing speed is 100 SCCM. Similarly, depending on the plated material of the PVD resistant alloy layer 105 utilized, a PVD transition layer can be formed between the PVD plasma glowing and the PVD resistant alloy layer 105. The technology involved is to sputter Cr using a DC current, the DC current is 5 A, bias is 100V, duty cycle is 38%, Ar gas flowing speed is 100 SCCM, with its duration of 3 minutes. Its purpose is to increase the binding force between the respective layers and reduce the stress between the respective layers

Then, perform bathing and sanitary equipment tests based on the following standards:
A. CASS=Copper-Accelerated Acetic Acid-Salt Spray (Fog) Testing (corrosion resistance test ASTM B368-09) . . . 0.8 h;
B. AASS=Acetic Acid-Salt Spray (Fog) Testing (salt mist test ASTM G85-9) . . . 0.48 h;
C. thermal cycling test −40° C. to 75° C. (ASME A112.18.1-2005/CSA B125.1-05) . . . 8 cycles.
   The tests are conducted and passed for all the items mentioned above.

### Embodiment 7

As shown in FIG. 1, the structure of ABS plastic surface metal layer 100, starting from the ABS plastic 101 in sequence, is as follows: a chemical nickel layer 102 having a thickness of 0.2 μm, a watt nickel layer 103 having a thickness of 2 μm, a semi-bright nickel layer 104 having a thickness of 6 μm, a PVD resistant alloy layer 105 having a thickness of 0.7 μm, the resistant alloy can be a ZrSi alloy (the ZrSi atom number percentage is Zr 90 and Si 10), and a PVD color layer 106 having a thickness of and that is made of TiN.

As shown in FIG. 2, the ABS plastic surface metal layer manufacturing method 200 includes the following steps:

(1) pre-processing the ABS plastic, to process ABS plastic in the following sequence: chemical degreasing→roughening→neutralizing→catalyzing→dispergating→chemical nickel; the process flow proceeds according to the existing technology, while the thickness of the plated chemical nickel layer 102 is 0.2 μm (step 201);

(2) electroplating the ABS plastic: after the first step of pre-processing ABS plastic, perform electroplating the watt nickel layer 103 and the semi-bright nickel layer 104. The electroplating of the watt nickel layer 103 utilizes the well known watt nickel recipe, the thickness of the watt nickel layer 103 is controlled at 2 μm; then perform electroplating the semi-bright nickel layer 104 utilizing the well known semi-bright nickel recipe, the thickness of the semi-bright nickel layer 104 is controlled at 6 μm, to meet the requirement of thickness for the dragging process (step 202);

(3) perform dragging process for ABS plastic plated nickel layer: perform dragging process after the second step of electroplating ABS plastic. The dragging can be performed manually or automatically. The rotation speed of the dragging machine is 600 r/min, while the dragging wheel can be a flying wing wheel (step 203); and

(4) after the dragging process, the ABS plastic plated piece is performed hydrocarbon vacuum degreasing and baking processes; to hang the product onto the PVD film forming hanging tool, to perform hydrocarbon vacuum degreasing and baking processes; the degreasing duration is 5 min, while the baking duration is 10 min. Afterwards, the ABS plastic plated piece is formed a PVD resistant alloy layer 105 and the PVD color layer 106. To hang the ABS plastic plated piece directly into the PVD oven, to form the PVD resistant alloy layer 105 and the PVD color layer 106 according to the following steps (step 204):

(1) vacuuming: when vacuum reaches 2×10⁻² Pa, perform plasma glowing process, the ion current is 1 A, bias is 180V, duty ratio is 30%, Ar gas flowing speed is 200 SCCM, duration is 5 min, in achieving the purpose of further cleaning;

(2) perform vacuuming: when vacuum reaches 5×10⁻³ Pa, form a sputtered PVD resistant alloy layer 105. The parameters utilized are as follows: intermediate frequency impulse DC power supply, intermediate frequency impulse power current 2 A, the sputtered target is pure silicon target, DC power current 12 A; the sputtered target is pure Zr target, deposition duration 30 min, bias is 100V, duty ratio is 25%, Ar gas flowing speed is 150 SCCM. The target for the PVD resistant alloy layer 105 can be a Zr target and an Si target; and

(3) upon finishing forming the PVD resistant alloy layer 105, continue vacuuming for 5 min, then form the PVD color layer 106, the parameters for this are as follows: multi-arc power current 70 A, deposition duration 5 min, bias is 100V, duty ratio is 80%, Ar gas flowing speed is 20 SCCM, N₂ gas flowing speed is 150 SCCM. The metal target for PVD color layer 106 can be pure Ti 99.99%.

Between the PVD resistant alloy layer 105 and the PVD color layer 106, a PVD transition layer has to be formed by sputtering Zr using a DC current. The parameters for this are as follows: power current 5 A, multi-arc Ti sputtering with current 70 A, deposition duration is 2 min, bias is 100V, duty cycle is 80%, Ar gas flowing speed is 100 SCCM. Similarly, depending on the material of the PVD resistant alloy layer 105 utilized, a PVD transition layer can be formed between the PVD plasma glowing and the PVD resistant alloy layer 105. The technology involved is to sputter the Zr using a DC current, the DC current is 5 A, bias is 100V, duty cycle is 38%, Ar gas flowing speed is 100 SCCM, with its duration 3 minutes. Its purpose is to increase the binding force between the respective layers and reduce the stress between the respective layers

Then, perform bathing and sanitary equipment tests based on the following standards:
A. CASS=Copper-Accelerated Acetic Acid-Salt Spray (Fog) Testing (corrosion resistance test ASTM B368-09) . . . 0.8 h;
B. AASS=Acetic Acid-Salt Spray (Fog) Testing (salt mist test ASTM G85-9) . . . 0.48 h;
C. thermal cycling test −40° C. to 75° C. (ASME A112.18.1-2005/CSA B125.1-05) . . . 8 cycles.
   The tests are conducted and passed for all the items mentioned above.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. An ABS plastic surface metal layer, comprising:
a structure, starting from an ABS plastic in sequence, is as follows: a chemical nickel layer having a thickness of 0.05˜0.5 μm, a watt nickel layer having a thickness of 1˜3 μm, a semi-bright nickel layer having a thickness of 3˜10 μm, a PVD resistant alloy layer having a thickness of 0.1˜2 μm, and a PVD color layer having a thickness of 0.1˜0.3 μm.

2. The ABS plastic surface metal layer as claimed in claim 1, wherein resistant alloy of said PVD resistant alloy layer is selected from at least one of a group consisting of: ZrSi alloy, CrSi alloy, NiCr alloy, and TiSi alloy.

3. An ABS plastic surface metal layer manufacturing method, comprising following steps:
(1) pre-processing said ABS plastic in following sequence: chemical degreasing→roughening→neutralizing→catalyzing→dispergating→chemical nickel;
(2) electroplating said watt nickel layer and the semi-bright nickel layer, for said pre-processed ABS plastic:
(3) performing dragging process for said plated semi-bright nickel layer of said ABS plastic; and
(4) performing hydrocarbon vacuum degreasing and baking processes for a dragged ABS plastic plated piece, then form said PVD resistant alloy layer and said PVD color layer, to complete producing said ABS plastic surface metal layer.

4. The ABS plastic surface metal layer manufacturing method as claimed in claim 3, wherein in said step (1), said pre-processing said ABS plastic is performed as based on existing technology.

5. The ABS plastic surface metal layer manufacturing method as claimed in claim 3, wherein in said step (2), said electroplating said watt nickel layer and said semi-bright nickel layer utilizes conventional watt nickel recipe and semi-bright nickel recipe to perform electroplating, first electroplating said watt nickel layer, and then electroplating said semi-bright nickel layer, thickness of said watt nickel layer is controlled at 1˜3 μm, while thickness of said semi-bright nickel layer is controlled at 3˜10 μm.

6. The ABS plastic surface metal layer manufacturing method as claimed in claim 3, wherein in said step (3), dragging is performed manually or automatically, rotation speed of a dragging machine is 600˜1200 r/min; while a dragging wheel is a nylon wheel or a flying wing wheel.

7. The ABS plastic surface metal layer manufacturing method as claimed in claim 3, wherein in said step (4), said performing hydrocarbon vacuum degreasing and baking process, is to hang a product on a PVD film forming hanging tool, to perform said hydrocarbon vacuum degreasing and baking processes, degreasing duration is 3˜8 minutes (min), baking duration is 5 10 min, said PVD resistant alloy layer and said PVD color layer are hung directly into a PVD oven to form said PVD resistant alloy layer and said PVD color layer, as based on following steps:
(1) vacuuming: when vacuum reaches 2×10⁻² Pa, perform plasma glowing process, the ion current is 0.7˜1 A, bias is 150˜200 V, duty ratio is 20˜38%, Ar gas flowing speed is 100˜300 SCCM, duration is 5˜10 min, in achieving purpose of further cleaning;
(2) perform vacuuming: when vacuum reaches (3˜9)×10⁻³ Pa, form said sputtered PVD resistant alloy layer utilizing following parameters: intermediate frequency impulse or DC power supply, power current 1˜20 A, deposition duration 5˜60 min, bias is 80˜100V, duty ratio is 20˜38%, Ar gas flowing speed is 60˜200 SCCM, N₂ gas flowing speed is 0˜100 SCCM, target for said PVD resistant alloy layer is at least one of following: ZrSi alloy target, CrSi alloy target, NiCr alloy target, and TiSi alloy target, or Zr target and Si target sputtered and deposited at the same time, or Cr target and Si target sputtered and deposited at the same time, or Ni target and Cr target sputtered and deposited at the same time, or ZTi target and Si target sputtered and deposited at the same time; and
(3) upon finishing forming said PVD resistant alloy layer, continue vacuuming for 3˜5 min, then form said PVD color layer based on following parameters: multi-arc power current 70˜120 A, deposition duration 2˜5 min, bias 80˜100V, duty ratio is 40˜80%, Ar gas flowing speed is 20˜200 SCCM, N₂ gas flowing speed is 0˜200 SCCM, acetylene gas flowing speed is 0˜150 SCCM, O₂ gas flowing speed is 0˜150 SCCM, metal target for said PVD color layer is one of following; pure Zr 99.99%, pure Ti 99.99%, and pure Cr 99.99%.

8. The ABS plastic surface metal layer manufacturing method as claimed in claim 7, wherein a PVD transition layer is formed between said PVD resistant alloy layer and said PVD color layer.

9. The ABS plastic surface metal layer manufacturing method as claimed in claim 7, wherein said PVD transition layer is formed between said PVD plasma glowing and said PVD resistant alloy layer with a duration of 1˜5 min.
